(19) United States
(12) Patent Application Publication
(10) Pub. No.: US 2013/0135120 A1
(43) Pub. Date: May 30, 2013

(54) KEYBOARD APPLICABLE TO A VARIETY OF ELECTRONIC PRODUCTS

(71) Applicants: LEI DENG, Shenzhen City (CN); WEI-MIN HE, Shenzhen City (CN)

(72) Inventors: LEI DENG, Shenzhen City (CN); WEI-MIN HE, Shenzhen City (CN)

(73) Assignees: HON HAI PRECISION INDUSTRY CO., LTD., Tu-Cheng (TW); HONGFU JIN PRECISION INDUSTRY (ShenZhen) CO., LTD, Shenzhen City (CN)

(21) Appl. No.: 13/370,323

(22) Filed: Feb. 10, 2012

(30) Foreign Application Priority Data
Nov. 25, 2011 (CN) 201110380712.7

(51) Int. Cl. H03M 11/00

(52) U.S. Cl. 341/22

(57) ABSTRACT

A keyboard to control an electronic product includes an input unit, a code switching unit, a decoding unit, and a wireless output unit. The input unit receives a manipulation instruction and sends an electrical signal corresponding to the manipulation instruction to the decoding unit. The code switching unit receives a decoding instruction and sends an electrical signal corresponding to the decoding instruction to the decoding unit. The decoding unit decodes the manipulation instruction to a command recognizable by the electronic product according to the decoding instruction. The wireless output unit is wirelessly connected to the electronic product, thereby transmitting the command to the electronic product.

### BACKGROUND

1. Technical Field

The present disclosure relates to a keyboard applicable to a variety of electronic products.

2. Description of Related Art

A typical mobile electronic product, such as a smart phone or a tablet personal computer, includes a touch screen for data inputting. Compared with inputting through a keyboard, inputting through a touch screen can be inefficient. Accordingly, some of these mobile electronic products can be matched with an optional keyboard for tasks requiring a lot of data inputting, such as editing an email, or publishing an article on the Internet. However, a typical keyboard can only match with a particular mobile electronic product. Thus, the versatility of the keyboard is limited.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a block diagram of a first exemplary embodiment of a keyboard, together with electronic products that can be used in conjunction with the keyboard.

FIG. 2 is a block diagram of a second exemplary embodiment of a keyboard, together with an electronic product that can be used in conjunction with the keyboard.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references can mean “at least one.”

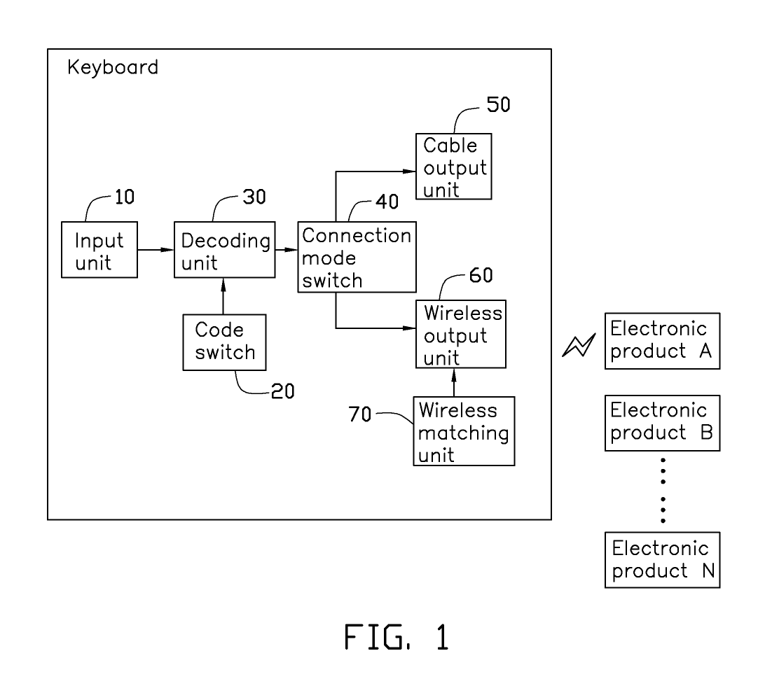

Referring to FIG. 1, a first exemplary embodiment of a keyboard includes an input unit 10, a code switch 20, a decoding unit 30, a connection mode switch 40, a cable output unit 50, a wireless output unit 60, and a wireless matching unit 70.

The input unit 10 receives a manipulation instruction of a user, and sends an electrical signal corresponding to the manipulation instruction to the decoding unit 30. In one embodiment, the input unit 10 includes a plurality of keys. The manipulation instruction is inputted to the input unit 10 by pressing one or more of the keys.

The code switch 20 receives from the user a selected one of a plurality of decoding instructions, and transmits the decoding instruction to the decoding unit 30. Each of the plurality of decoding instructions corresponds to a particular type of electronic product, such as a personal computer (PC), or a smart phone, or a tablet PC.

The decoding unit 30 converts the manipulation instruction to a command recognizable by the type of electronic product corresponding to the decoding instruction.

The connection mode switch 40 is operated by the user to selectively make the keyboard work in a cable connection mode or a wireless connection mode. When the keyboard works in the cable connection mode, the command generated by the decoding unit 30 is transmitted to the cable output unit 50, and further transmitted to an electronic product through a cable connected between the electronic product and the cable output unit 50. When the keyboard works in the wireless connection mode, the command is transmitted to the wireless output unit 60, and further transmitted to an electronic product by wireless telecommunication such as wireless fidelity (Wi-Fi) or radio frequency (RF).

The wireless matching unit 70 is operated by the user to make the wireless output unit 60 match with one of electronic products capable of wirelessly connecting with the wireless output unit 60. For example, the wireless output unit 60 provides a Wi-Fi connection mode, and detects a number of electronic products capable of connecting with the wireless output unit 60 by Wi-Fi. One of the electronic products is selected by the user operating the wireless matching unit 70, in order to match the wireless output unit 60 with the electronic product, so that the electronic product receives the command generated by the decoding unit 30.

When the keyboard is used to control an electronic product A through wireless telecommunication, a decoding instruction corresponding to the type of electronic product that electronic product A is inputted by a user to the code switch 20, and transmitted to the decoding unit 30. The connection mode switch 40 is operated by the user to make the keyboard work in the wireless connection mode. Thereby, the wireless output unit 60 is activated and detects electronic products A, B . . . N. The wireless matching unit 70 is operated by the user to make the wireless output unit 60 match with the electronic product A. Then, to control the electronic product A, manipulation instructions are inputted to the input unit 10 by the user and are decoded to corresponding commands, which are transmitted to the electronic product A by wireless telecommunication, and are recognized by the electronic product A.

When the keyboard is used to control an electronic product (not shown) through a cable connection, a cable is connected between the electronic product and the cable output unit 50. A decoding instruction corresponding to the type of electronic product that the electronic product is inputted by a user to the code switch 20, and transmitted to the decoding unit 30. The connection mode switch 40 is operated by the user to make the keyboard work in the cable connection mode. Thereby, the cable output unit 50 is activated. Then, to control the electronic product, manipulation instructions are inputted to the input unit 10 by the user and are decoded to corresponding commands, which are transmitted to the electronic product through the cable, and are recognized by the electronic product.

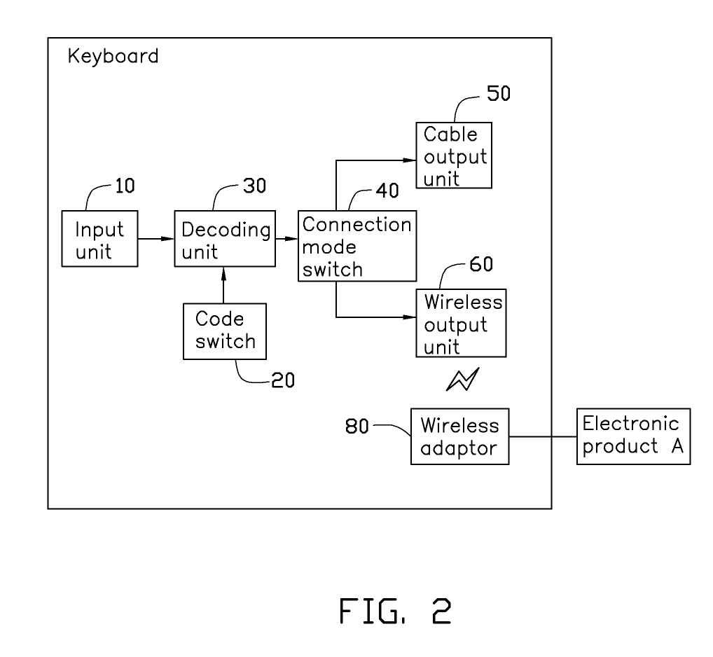

Referring to FIG. 2, a second exemplary embodiment of a keyboard includes an input unit 10, a code switch 20, a decoding unit 30, a connection mode switch 40, a cable output unit 50, a wireless output unit 60, and a wireless adaptor 80 matched with the wireless output unit 60. The input unit 10, the code switch 20, the decoding unit 30, the connection mode switch 40, the cable output unit 50, and the wireless output unit 60 are same as those of the keyboard of the first exemplary embodiment.

When the keyboard of the second exemplary embodiment is used to control an electronic product A through wireless telecommunication, the wireless adaptor 80 is coupled to the electronic product A. A decoding instruction corresponding to the type of electronic product that electronic product A is inputted by a user to the code switch 20, and transmitted to the decoding unit 30. The connection mode switch 40 is operated by the user to make the keyboard work in a wireless connection mode. Thereby, the wireless output unit 60 detects the wireless adaptor 80, and matches with the wireless adaptor 80. Then, to control the electronic product A, manipulation instructions are inputted to the input unit 10 by the user, and are decoded to corresponding commands, which are transmitted to the electronic product A by wireless telecommunication, and are recognized by the electronic product A.

When the keyboard of the second exemplary embodiment is used to control an electronic product (not shown) through a cable connection, a cable is connected between the electronic product and the cable output unit 50. A decoding instruction corresponding to the type of electronic product that the electronic product is inputted by a user to the code switch 20, and transmitted to the decoding unit 30. The connection mode switch 40 is operated by the user to make the keyboard work in the cable connection mode. Thereby, the cable output unit 50 is activated. Then, to control the electronic product, manipulation instructions are inputted to the input unit 10 by the user and are decoded to corresponding commands, which are transmitted to the electronic product through the cable, and are recognized by the electronic product.

It is to be understood, however, that even though numerous characteristics and advantages of the embodiments have been set forth in the foregoing description, together with details of the structures and functions of the embodiments, the disclosure is illustrative only, and changes may be made in detail, especially in the matters of arrangement of parts within the principles of the present disclosure to the full extent indicated by the broad general meaning of the terms in which the appended claims are expressed.

What is claimed is:

1. A keyboard to control a selected electronic product, comprising:
an input unit configured to receive a manipulation instruction of a user;
a code switch configured to receive a decoding instruction of the user, the decoding instruction corresponding to the type of electronic product that the electronic product is;
a decoding unit configured to receive electronic signals respectively sent from the input unit corresponding to the manipulation instruction and from the code switch corresponding to the decoding instruction, and to decode the manipulation instruction to a command according to the decoding instruction, the command being recognizable by the electronic product; and
a wireless output unit configured to be wirelessly connected to the electronic product and thereby transmit the command to the electronic product.

2. The keyboard of claim 1, wherein the command is transmitted to the electronic product by wireless fidelity (Wi-Fi) or radio frequency (RF).

3. The keyboard of claim 1, further comprising a connection mode switch, and a cable output unit to connect to the electronic product through a cable, wherein the connection mode switch is operable by a user to selectively make the keyboard work in either a cable connection mode to transmit the command to the electronic product through the cable output unit, or a wireless connection mode to transmit the command to the electronic product through the wireless output unit.

4. The keyboard of claim 1, further comprising a wireless adaptor electrically coupled to the electronic product, wherein the wireless output unit is configured to detect and match with the wireless adaptor.

5. The keyboard of claim 1, further comprising a wireless matching unit, wherein the wireless matching unit is operable by a user to make the wireless output unit match with the electronic product, which is one electronic product among a plurality of electronic products detected by the wireless output unit.

6. The keyboard of claim 5, wherein the plurality of electronic products are any one or more items selected from the group consisting of personal computers (PCs), smart phones, and tablet PCs.

7. The keyboard of claim 1, wherein the type of electronic product that the electronic product is selected from the group consisting of a personal computer (PC), a smart phone, and a tablet PC.

8. An electronic combination comprising:
an electronic product; and
a keyboard comprising:
an input unit configured to receive a manipulation instruction of a user;
a code switch configured to receive a decoding instruction of the user, the decoding instruction corresponding to the type of electronic product that the electronic product is;
a decoding unit configured to receive electronic signals respectively sent from the input unit corresponding to the manipulation instruction and from the code switch corresponding to the decoding instruction, and to decode the manipulation instruction to a command according to the decoding instruction, the command being recognizable by the electronic product; and
a connection mode switch operable by a user to selectively make the keyboard work in either a cable connection mode to transmit the command to the electronic product through a cable, or a wireless connection mode to transmit the command to the electronic product through wireless telecommunication.

9. The electronic combination of claim 8, wherein the keyboard further comprises a cable output unit configured to be connected with the electronic product through a cable, and a wireless output unit configured to be connected with the electronic product through the wireless telecommunication; the cable output unit is activated in response to the keyboard working in a cable connection mode; and the wireless output unit is activated in response to the keyboard working in a wireless connection mode.

10. The electronic combination of claim 9, wherein the keyboard further comprises a wireless matching unit operable to make the wireless output unit match with the electronic product, which is one electronic product among a plurality of electronic products detected by the wireless output unit.

11. The electronic combination of claim 10, wherein the plurality of electronic products are any one or more items selected from the group consisting of personal computers (PCs), smart phones, and tablet PCs.

12. The electronic combination of claim 9, wherein the command is transmitted to the electronic product by wireless fidelity (Wi-Fi) or radio frequency (RF) in response to the keyboard working in the wireless connection mode.

13. The electronic combination of claim 8, wherein the electronic product is selected from the group consisting of a personal computer (PC), a smart phone, and a tablet PC.
